(19) United States
(12) Patent Application Publication
(10) Pub. No.: US 2014/0322833 A1
(43) Pub. Date: Oct. 30, 2014

(54) IRRADIATION APPARATUS FOR IRRADIATING CHARGED PARTICLE BEAM, METHOD FOR IRRADIATION OF CHARGED PARTICLE BEAM, AND METHOD FOR MANUFACTURING ARTICLE

(71) Applicant: Canon Kabushiki Kaisha, Tokyo (JP)

(72) Inventors: Wataru Yamaguchi, Utsunomiya-shi (JP); Hideki Ina, Tokyo (JP); Masato Muraki, Inagi-shi (JP)

(73) Assignee: Canon Kabushiki Kaisha, Tokyo (JP)

(21) Appl. No.: 14/256,779

(22) Filed: Apr. 18, 2014

(30) Foreign Application Priority Data
Apr. 24, 2013 (JP) 2013-091563
Feb. 13, 2014 (JP) 2014-025733

(51) Int. Cl. H01J 37/304; H01L 21/268; H01L 21/66; H01J 37/317

(52) U.S. Cl. CPC H01J 37/3045; H01J 37/3174; H01L 21/268; H01L 22/12
USPC 438/14; 250/398

(57) ABSTRACT

An apparatus includes an optical system configured to irradiate a substrate with a charged particle beam, a control unit configured to control an irradiation position of the charged particle beam, and a first measurement unit and a second measurement unit each configured to measure a surface position of the substrate. The first measurement unit and the second measurement unit have different characteristics in terms of charging. The control unit controls the irradiation position of the charged particle beam based on values measured by the first measurement unit and the second measurement unit.

### BACKGROUND OF THE INVENTION

1. Field of the Invention

The present invention relates to an irradiation apparatus for irradiating a charged particle beam which irradiates a charged particle beam to a surface of a substrate, a method for irradiation of a charged particle beam, and a method for manufacturing an article.

2. Description of the Related Art

An electron beam drawing method is known as one of the methods for transferring a circuit pattern to a resist in a lithography process for manufacturing a semiconductor integrated circuit. The electron beam drawing method is a method for converging electron beams emitted from an electron source on a substrate and drawing a pattern by scanning the converged electron beam. This method may be advantageous over a conventional exposure system in that various patterns can be transferred without a mask.

However, since the electron beam drawing method is performed by irradiating electrons carrying charge, the charging of the surface of the substrate causes an orbit of the electron beam to be curved, resulting in deviation of the irradiation position.

When the resist applied on the substrate is irradiated with the electron beam, secondary electrons are emitted around the substrate or positive charges are stored on the resist surface. The electrically charged surface of the substrate caused by this phenomenon and a grounded peripheral portion of the substrate causes formation of an equipotential surface, for example, as indicated by a broken line in FIG. 8A.

In this case, axes orthogonal to an equipotential surface 82 near the outer edge of a substrate 3 easily deviate from a Z axis direction. As a result, an electron beam 81 applied closer to the outer edge is affected more by charging to easily change the orbit, so that the drawing position easily deviates on an XY plane as shown in FIG. 8B. Thus, there is known a phenomenon of a deviation between a set pattern and an actually drawn pattern.

In a device manufacturing process for stacking a plurality of semiconductor layers, the deviation of the drawing position on each of the layers will lead to reduction of overlay accuracy. Thus, this phenomenon cannot be ignored any more as circuit patterns become finer and more complex.

As a method for correcting the deviation of a drawing position caused by a charge distribution on the circumference of a substrate, Japanese Patent Application Laid-Open No. 2007-324175 discusses a technique for obtaining the electric field intensity of the substrate surface by calculation. In this method, the electric field intensity generated at the irradiation position of an electron beam and around the position is calculated, and the positional deviation of drawing with the electron beam is corrected based on the calculated electric field intensity.

Further, Japanese Patent Application Laid-Open No. 2011-243957 discusses a technique for measuring the deviation of a drawing position by applying light and an electron beam to a mark for aligning a drawing pattern (hereinafter, referred to as an alignment mark). In this method, the reflected position of the light applied to the alignment mark is detected by a photodetector, secondary electrons generated from the irradiation position of the electron beam are detected by a secondary electron detector, and then a difference in the measurement results between the two detectors is corrected as the positional deviation of drawing with the electron beam.

In addition to the phenomenon of charging in a wide area shown in FIGS. 8A and 8B, considering the phenomenon of a local charging due to the influence of the process for a resist underlayer on the electron beam applied to the resist, further improvement of correction accuracy is desired.

The method discussed in Japanese Patent Application Laid-Open No. 2007-324175, in which the electric field intensity is obtained by calculation, may cause a large difference between the actual charge distribution and the calculated charge distribution. Further, the method discussed in Japanese Patent Application Laid-Open No. 2011-243957 is based on actual measurement, but the alignment mark is a measurement target and therefore restrictions are imposed on the measurement position.

### SUMMARY OF THE INVENTION

The present invention is directed to an irradiation apparatus for irradiating a charged particle beam capable of correcting a deviation of an irradiation position caused by charging of a substrate surface.

According to an aspect of the present invention, an apparatus for irradiating a charged particle beam includes an optical system configured to irradiate a substrate with the charged particle beam, a control unit configured to control an irradiation position of the charged particle beam, and a first measurement unit and a second measurement unit each configured to measure a surface position of the substrate. The first measurement unit and the second measurement unit have different characteristics in terms of charging. The control unit controls the irradiation position of the charged particle beam on the substrate based on values measured by the first measurement unit and the second measurement unit.

Further features of the present invention will become apparent from the following description of exemplary embodiments with reference to the attached drawings.

### BRIEF DESCRIPTION OF THE DRAWINGS

FIG. 1 is a diagram illustrating a configuration of a drawing apparatus according to a first exemplary embodiment.

FIG. 2 is a diagram illustrating an arrangement of a capacitance sensor according to the first exemplary embodiment.

FIG. 3 is a flowchart illustrating processing for correcting a deviation of a drawing position according to the first exemplary embodiment.

FIGS. 4A to 4C are diagrams illustrating a method for calculating a deviation of a drawing position based on a surface position.

FIG. 5 is a flowchart illustrating processing for correcting a deviation of a drawing position according to a second exemplary embodiment.

FIG. 6 is a diagram illustrating a configuration of a first and a second surface position measurement units according to a third exemplary embodiment.

FIG. 7 is a flowchart illustrating processing for correcting a deviation of a drawing position according to a fifth exemplary embodiment.

FIGS. 8A and 8B are diagrams illustrating a deviation of a drawing position caused by the influence of charging.

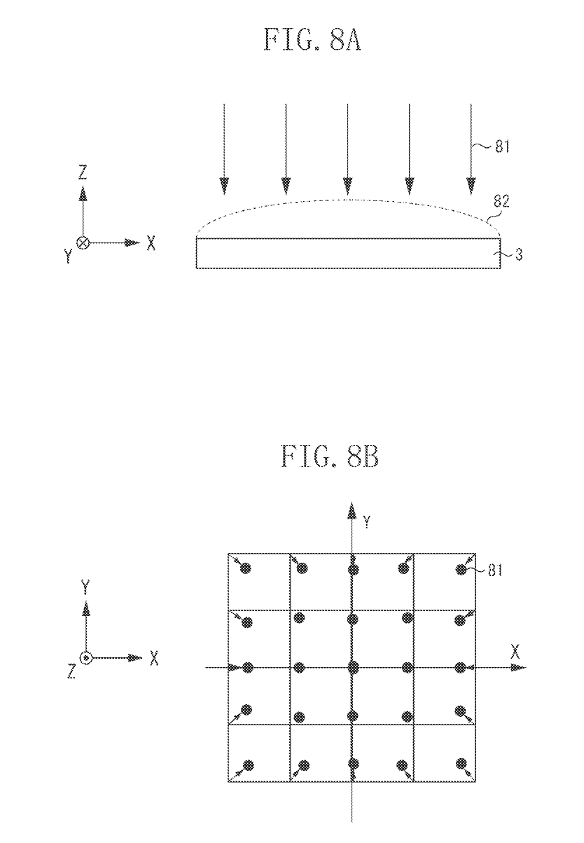

### DESCRIPTION OF THE EMBODIMENTS

Hereinafter, an irradiation apparatus for irradiating a charged particle beam according an exemplary embodiment of the present invention will be described using an example of a drawing apparatus for drawing a pattern with one converged electron beam. However, the number of electron beams is not limited thereto. Ion beams may also be used as charged particle beams other than electron beams. An exemplary embodiment of the present invention is not limited to the drawing apparatus, and is applicable to various types of apparatuses for performing processing or measurement with charged particle beams.

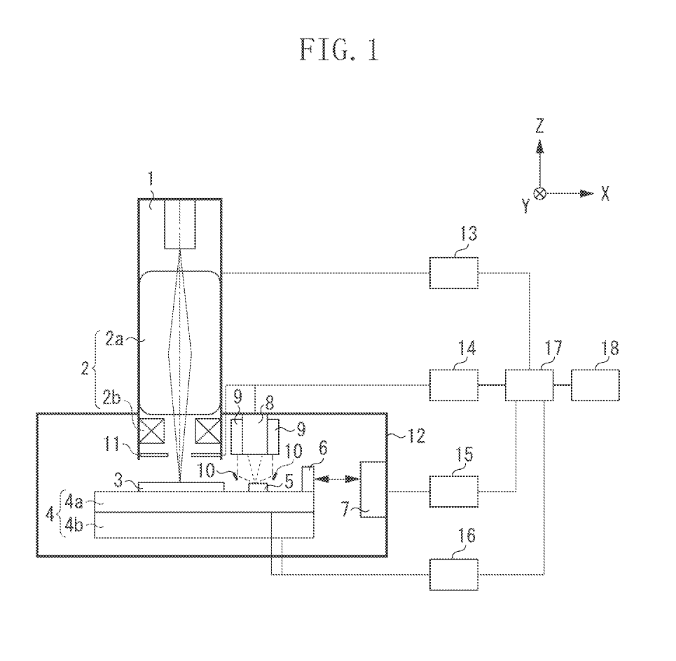

First, a configuration of a drawing apparatus according to a first exemplary embodiment will be described referring to FIG. 1.

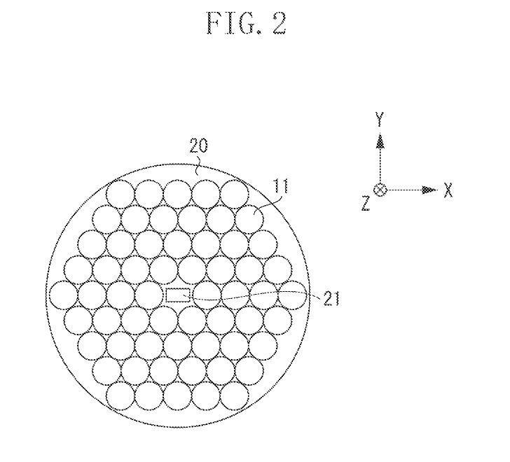

An irradiation unit for emitting a charged particle beam 20 (illustrated in FIG. 2) includes an electron source 1 for emitting electron beams, and an electronic optical system 2 serving as a charged particle optical system. The electron beams emitted from the electron source 1 are applied to a surface layer on the substrate 3 via the electronic optical system 2. The electronic optical system 2 includes an electronic lens system 2a and a deflector 2b. The electronic lens system 2a, which has received an instruction from a control unit 13 (described below), converges the electron beams emitted from the electron source 1, and the deflector 2b deflects the converged electron beam in an X axis direction and a Y axis direction. The deflector 2b further changes the degree of deflection of the electron beam so that the irradiation of the substrate 3 can be switched on and off in a short time.

A stage 4 includes an X stage 4a, a Y stage 4b, and a Z stage 4c. The substrate 3 is held on the stage 4, and moved in the X axis direction by the X stage 4a, in the Y axis direction by the Y stage 4b, and in a Z axis direction by the Z stage 4c.

On the stage 4, a reference plate 5 with a reference mark formed is installed at a position different from that of the substrate 3. At one end on the X stage 4a, a reflection mirror 6 for determining the position of the substrate 3 in the X axis direction is disposed. Similarly, a reflection mirror (not illustrated) is disposed on the Y stage 4b. The stage 4 is not limited to the configuration according to the present exemplary embodiment, as long as the stage 4 holding the substrate 3 is movable in the X, Y and Z axis directions.

An interferometer 7 measures the position of the stage 4 in the X axis direction by emitting a laser beam to the reflection mirror 6. The laser beam emitted from a light source of the interferometer 7 is divided into measurement light and reference light different from each other in frequency. The measurement light enters the reflection mirror 6, and the reference light enters a reference mirror (not illustrated) inside the interferometer 7. The light reflected by the reflection mirror 6 and the light reflected by the reference mirror are superimposed one on another to interfere with each other, and the frequency of the interference light is detected by using a detector of the interferometer 7. Thus, a position detection unit 15 measures the position of the stage 4 in the X axis direction with respect to an optical path length of the reference light.

Further, the reflection mirror 6 moves with the movement of the stage 4. This causes the frequency of the light reflected by the reflection mirror 6 to change by Δf. Accordingly, a signal detected by the detector of the interferometer 7, which indicates the frequency of the interference light, also changes by Δf. The position detection unit 15 processes this beat signal so that the moving amount of the stage 4 can be obtained. Similarly, the position of the stage 4 in the Y axis direction is measured by an interferometer (not illustrated) for detecting the position of the stage 4 in the Y axis direction.

An alignment optical system 8 irradiates an alignment mark on the substrate 3 or the reference mark formed on the reference plate 5 with light of a wavelength band where the resist will not be exposed to light. By forming an image of reflected light from the light on a sensor of the alignment optical system 8, the position of the alignment mark or the reference mark on an XY plane is detected.

An optical focus sensor 9 serving as a first measurement unit is located near the alignment optical system 8, and measures a surface position using a light projecting system 9a and a light receiving system 9b. Hereinafter, it is assumed that the surface position is a distance from each of various sensors to the surface of the substrate 3 in the Z axis direction. The light projecting system 9a causes light to be incident on the substrate 3, which is a measurement target, obliquely from above, and the light receiving system 9b receives reflected light from the substrate 3. The surface position is obtained from an intensity distribution of the reflected light. The optical focus sensor 9 can measure the surface position of the substrate 3 without being affected by charge generated at the circumference of the substrate 3.

When the surface position is measured by using the optical focus sensor 9 as in the case of the present exemplary embodiment, it is desired that consideration be given to the light source of the optical focus sensor 9 so that measurement errors caused by the process for the substrate 3 can be reduced. This is because the measurement by the optical focus sensor 9 may be affected by the reflected light on a boundary surface between the resist layer and a layer positioned thereunder or by the pattern density of the semiconductor layers formed on the substrate 3, thereby causing measurement errors. The degree of measurement errors depends on the wavelength of a light source or the reflectance of the layer positioned under the resist layer. Thus, the surface position is to be obtained based on the center-of-gravity position of a signal to be measured, by using not light of a single wavelength but light of a wide wavelength band as a light source.

Here, the light of a wide wavelength band indicates light including peak wavelengths as many as possible, and light may have a peak wavelength of 400 nm or more. Light continuously may include a wavelength band of 450 nm to 800 nm is more. This is because, if the substrate 3 is irradiated with ultraviolet light (with a wavelength of 400 nm or less), the resist applied on the substrate 3 may be changed due to the ultraviolet light.

An example of the optical focus sensor 9 is an optical sensor that includes a halogen lamp or a white light-emitting diode (LED), which emits light of a wide wavelength band. A white interference sensor that divides light of a wide wavelength band into measurement light and reference light to cause the light reflected on a measurement target and the light reflected on a reference surface to interfere with each other may be used. Alternatively, a wavelength scanning-type light source capable of scanning a single wavelength in a wide wavelength band may be used.

The location of the optical focus sensor 9 is not limited to the vicinity of the alignment optical system 8 as in the case of the present exemplary embodiment. The optical focus sensor 9 may be disposed at the lower end of portion of the electronic optical system 2 or other places. However, when a sensor of a large size such as the optical focus sensor 9 having a white light source is used, it is difficult to dispose the sensor in a narrow space such as the lower end portion of the electronic optical system 2. Accordingly, the sensor should be located at a place with fewer space limitations. A particularly place may be near the alignment optical system 8 because the sensor can also serve as a focus sensor used for measuring the alignment mark.

A surface position measurement device serving as a second measurement unit is a capacitance sensor 11. The capacitance sensor 11 can be disposed at the lower end portion of the electronic optical system 2, for example, as illustrated in FIG. 1, because the capacitance sensor 11 is compact compared with the optical focus sensor 9 and has fewer limitations in arrangement. The capacitance sensor 11 measures a surface position by obtaining capacitance between the substrate 3 and an electrode of the capacitance sensor 11. To measure the surface position, a relational expression C=(ε·S)/D is used, where C is a capacitance between the substrate 3 and the electrode of the capacitance sensor 11, ε is an electric permittivity between the substrate 3 and the electrode of the capacitance sensor 11, S is a measurement area of the capacitance sensor 11, and D is a surface position of the substrate 3.

Using the capacitance sensor 11 allows measurement of surface positions of a plurality of points on the same substrate including an area where a circuit pattern is to be drawn with an electron beam excluding a scribe line (hereinafter, referred to as pattern area). Here, the measured surface position is the average of surface positions in the measurement area of each capacitance sensor 11. Accordingly, to measure a more local surface position, the capacitance sensor 11 having a small measurement area may be arranged at a plurality of places. This enables simultaneous evaluation of surface positions in areas (the measurement area per sensor x the number of sensors) including the pattern area.

FIG. 2 illustrates an example where the capacitance sensor 11 is disposed at the lower end portion of the electronic optical system 2. In FIG. 2, the capacitance sensor 11 is viewed from the substrate 3 side. An electron beam exit 21 is formed in the center of a bottom surface 20 at the bottom end of the electronic optical system, and a plurality of capacitance sensors 11 is located around the electron beam exit 21. In the present exemplary embodiment, the diameter of the capacitance sensor 11 may be 2 mm or more to 50 mm or less, and may be 2 mm or more to 10 mm or less. Thus, even when the surface position of the substrate 3 is measured from a position away from a surface position appropriate for measurement by using the capacitance sensor 11, measurement errors can be reduced.

The size and the arrangement location of the capacitance sensor 11 illustrated in FIG. 2 are only examples, and thus are in no way limitative. The capacitance sensor 11 may be arranged to occupy about a half of an area of the lower end portion of the electronic optical system, or a plurality of capacitance sensors 11 forming a small group may be arranged in several dispersed places.

A measured value obtained by the capacitance sensor 11 changes due to the influence of the amount of charge stored on the surface of the substrate 3. Consequently, the measured value includes an error according to the amount of charge. On the other hand, a measured value obtained by the optical focus sensor 9 does not include any measurement error due to charging. Thus, by comparing the measured values obtained by the two sensors with each other, a difference can be regarded as a value changed by the influence of charging.

Thus, the two types of surface position measurement devices used in the present exemplary embodiment are measurement devices having different characteristics in terms of charging. The term “having difference characteristics in terms of charging” indicates whether a main cause of the measurement error is the amount of charge stored on the surface of the substrate 3 in characteristics of the measurement device, and does not indicates a difference in error level between measurement devices of the same type.

To correct the deviation of a drawing position based on the surface position, measurement errors other than those caused by the charge distribution may be suppressed as much as possible during measurement of the surface position by both of the measurement devices.

In the measured value of the surface position obtained by the optical focus sensor 9 and the measured value of the surface position obtained by the capacitance sensor 11, initial offset occurs by the influence of the resist and/or the semiconductor layer under the resist layer due to a difference in measurement principle. When initial offset occurs depending on the type of a measurement device, the offset is to be corrected by using information, such as characteristic values of the resist and the semiconductor material, or a pattern to be drawn, stored in a memory 18 (described below). Based on the surface positions measured by the optical focus sensor 9 and the capacitance sensor 11 in the same area on the substrate, initial offset may be obtained for correction. When the value of the initial offset is uniform in all areas of the substrate 3, the offset can be corrected by using each of the measurement devices to measure the surface position of the reference plate 5 that will not be affected by charging.

Referring back to the configuration of the drawing apparatus illustrated in FIG. 1, each of the above-described members constituting the drawing apparatus is disposed in a vacuum chamber 12, and the inside of the vacuum chamber 12 is subjected to vacuum exhaustion by a vacuum pump (not illustrated).

Control units in the drawing apparatus according to the present exemplary embodiment include a control unit 13 that controls the electronic optical system 2, a control unit 14 that controls the measurement devices, the position detection unit 15, a control unit 16 that controls the position of the stage 4, and a main control unit 17. However, the control unit according to the present exemplary embodiment is only required to include at least the control unit 13, the control unit 16, and the main control unit 17. As long as functions of the control units are not affected, as illustrated in FIG. 1, the control units may be independently arranged, or integrally arranged on one circuit board.

The control unit 13, which is connected to the electron source 1 and the electron optical system 2, controls the electronic lens system 2a and the deflector 2b based on a command from the main control unit 17. The control unit 13 switches on and off the electron source 1. The control unit 13 further adjusts a voltage applied to the deflector 2b to control the degree of deflection of an electron beam, and controls an irradiation position where the substrate 3 is to be irradiated with the electron beam. By increasing the degree of the deflection and blocking the electron beam by a metal plate, switching on and off of irradiation of the substrate 3 can be controlled. Thus, by controlling the timing or position of irradiation with the electronic beam, the control unit 13 performs control to draw a pattern set by a user. Further, the control unit 13 can control aberration correction or a converging position of the electron beam by adjusting a voltage or current to be applied to an element of the electronic lens system 2a.

The control unit 14, which is connected to the alignment optical system 8, the optical focus sensor 9, and the capacitance sensor 11, issues an instruction for execution of measurement to each measurement device in response to an instruction from the main control unit 17.

The position detection unit 15, which is connected to the interferometer 7, obtains the position of the stage 4 based on a beat signal detected by the interferometer 7. The control unit 16 moves the X stage 4a, the Y stage 4b, and the Z stage 4c in response to an instruction from the main control unit 17. To correct the deviation of the irradiation position, the control unit 16 controls the electron beam irradiation position of the substrate 3 in a direction intersecting the optical axis of the optical system based on the measurement result of the optical focus sensor 9 or the capacitance sensor 11.

The control unit 16 further controls relative positions of the substrate 3 and the electronic optical system 2 in the Z axis direction to be constant when the irradiation is performed, and relative positions of the substrate 3 and the alignment optical system 8 in the Z axis direction to be constant when the alignment mark is measured. The surface position measurement for keeping constant the relative positions of the substrate 3 and the electronic optical system 2 and the relative positions of the substrate 3 and the alignment optical system 8 in the Z axis direction is executed by the capacitance sensor 11, the optical focus sensor 9, or a combination of these measurement devices. Thus, costs or space necessary for separately arranging focus measurement devices can be reduced.

The main control unit 17 is connected to the control unit 13, the control unit 14, the position detection unit 15, and the control unit 16. The main control unit 17 uses a central processing unit (CPU) held therein to cause the other control units to execute a program stored in the memory 18. At this time, the main control unit 17 executes reading of a program in the memory 18, various arithmetic operations, and storage of data transmitted from each measurement device in the memory 18.

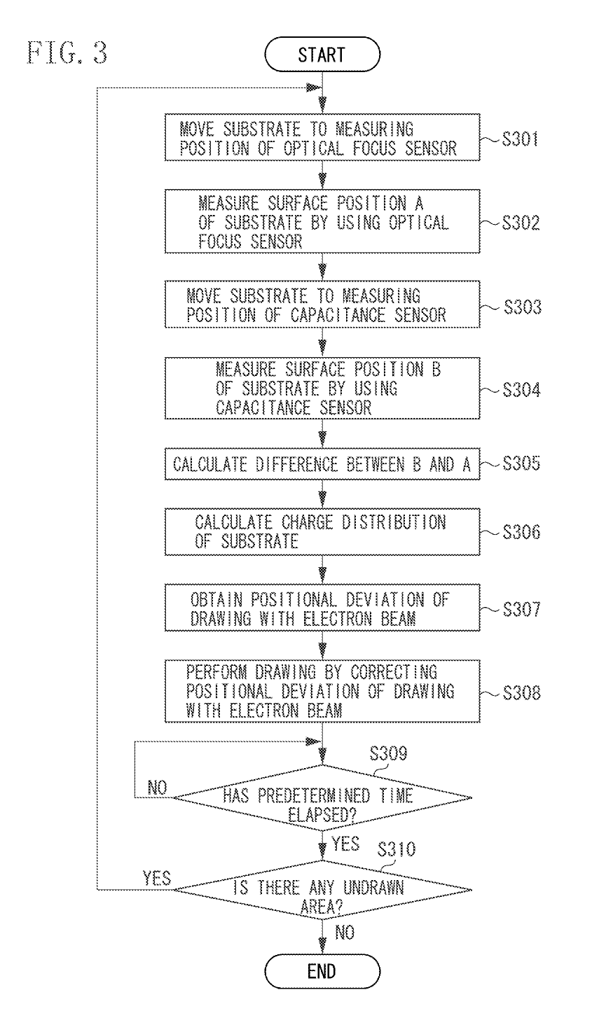

The memory 18 stores a program for implementing a flowchart illustrated in FIG. 3, measured values transmitted from each measurement device, and data indicating a relationship between the amount of charge and the positional deviation of the electron beam. The memory 18 further stores characteristics of various resists and the oxide film of a resist underlayer (e.g., threshold value energy, film thickness, and a relative permittivity), and various kinds of drawing patterns.

The main control unit 17 instructs each control unit to execute a program stored in the memory 18 so that the surface position measurement of the substrate 3 and the correction of a positional deviation during drawing are executed. Hereinafter, a series of processes for correcting the deviation of a drawing position will be described referring to the flowchart illustrated in FIG. 3. It is assumed that the timing of starting the processing in the flowchart is when drawing is being carried out on the substrate 3. First, in step S301, the drawing with an electron beam is interrupted, and the control unit 16 controls the stage 4 to move the substrate 3 to a measurement position of the optical focus sensor 9.

In step S302, the optical focus sensor 9, which has received an instruction from the control unit 14, measures the surface position of the substrate 3. Hereinafter, a first measured value obtained by the optical focus sensor 9 will be referred to as a surface position A, and a value of the surface position A will be stored in the memory 18. An area for measuring the surface position A is an area when drawing with an electron beam is to be performed before re-measurement by the optical focus sensor 9. At this time, to improve correction accuracy of positional deviation of the drawing, a pattern area may be included as a measurement area.

In step S303, the control unit 16 moves the substrate 3 to a measurement position of the capacitance sensor 11. In step S304, the control unit 104 causes the capacitance sensor 11 to measure the surface position of the substrate 3. Hereinafter, a second measured value obtained by the capacitance sensor 11 will be referred to as a surface position B, and a value of the surface position B will also be stored in the memory 18. An area for measuring the surface position B is the same as the measurement area for the optical focus sensor 9 in step S302.

In step S305, the main control unit 17 calculates a difference between measured values of the surface positions (surface position B—surface position A) for each position on the XY plane on the substrate 3. The surface position B is a value including an error caused by charge on the surface of the substrate 3, while the surface position A is not affected by the charge. Accordingly, the different between the surface position A and the surface position B is caused by charge on the surface of the substrate 3. Thus, in step S306, the main control unit 17 obtains a measurement error of capacitance equivalent to the difference between the surface positions, and calculates the amount of charge corresponding to the obtained value. By calculating the amount of charge in all areas where surface position measurement has been performed, a charge distribution on the surface of the substrate 3 can be obtained.

In step S307, deviation of an orbit of the applied electron beam is obtained based on the charge distribution calculated in step S306. At this time, the main control unit 17 refers to the data indicating the relationship between the amount of charge and the positional deviation of the electron beam previously stored in the memory 18. The data indicating the relationship between the amount of charge and the positional deviation of the electron beam may be data obtained by measurement or data obtained by calculation.

In step S308, the main control unit 17 instructs the other control unit to perform drawing while correcting the deviation of the drawing position. The control unit to be instructed by the main control unit 17 is one of the control unit 16 and the control unit 13, or a combination of both. One of specific correction methods is that the control unit 16 moves the stage 4 parallel in a direction for canceling the deviation of the drawing position. Another method is that the control unit 13 controls the electron beam irradiation position by adjusting a voltage of the deflector 2b after rewriting pattern data of an unirradiated area to cancel the deviation of a drawing position or directly without rewriting the pattern data.

In step S309, the main control unit 17 determines whether a predetermined time has elapsed since the surface position measurement. When it is determined that the predetermined time has elapsed (YES in step S309) and the correction timing has come again, then in step S310, the main control unit 17 determines whether there is any unirradiated area. When it is determined that the predetermined time has not elapsed (NO in step S309), the processing stands by until the predetermined time elapses. When it is determined that there is an unirradiated area (YES in step S310), the processing returns to step S301 to perform the surface position measurement and the operation of correcting the deviation of the drawing position again. When it is determined that there is no unirradiated area (NO in step S310), the program is ended.

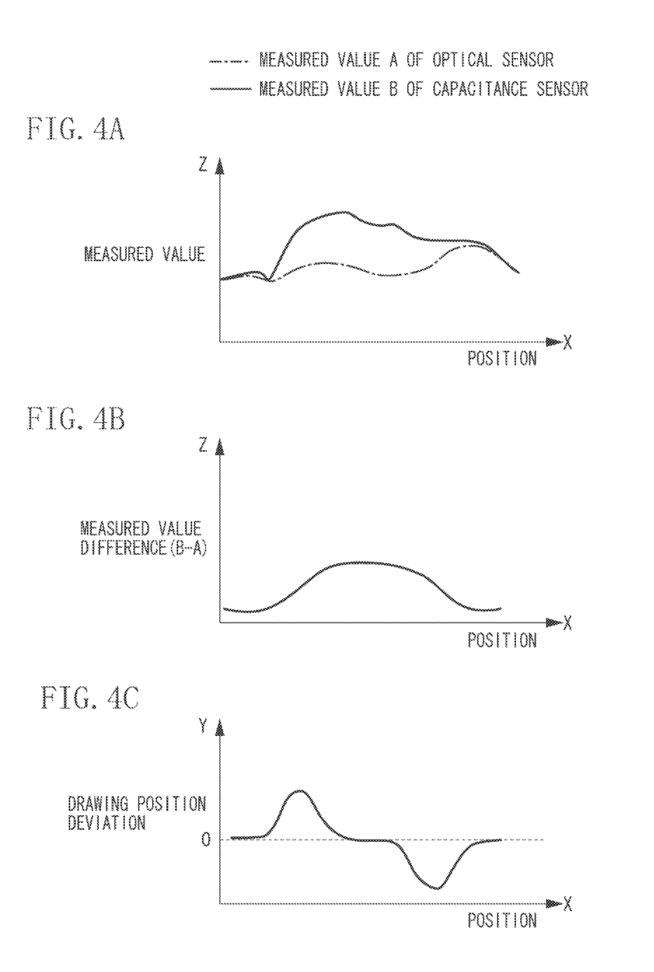

In the procedure from step S305 to S307, a height map may be used to obtain the deviation amount of the drawing position. A calculation method using the height map will be described referring to FIG. 3. FIG. 4A illustrates the surface position A measured in step S302, the surface position B measured in step S304, and a height map created based on the position coordinates thereof. To calculate a difference between the surface position A and the surface position B, a difference between graphs of the surface position A and the surface position B is calculated so that a graph illustrated in FIG. 4B is obtained. Deviation of the drawing position on the XY plane obtained based on the graph illustrated in FIG. 4B is represented by a graph illustrated in FIG. 4C.

The order of measurement by the optical focus sensor 9 and measurement by the capacitance sensor 11 can be reversed. With the configuration of the drawing apparatus illustrated in FIG. 1, irradiation with the electron beam, and surface position measurement in an unirradiated area using the capacitance sensor 11 can be performed in parallel. In this case, the processing from step S305 to step S307 can be executed at any timing as long as it is executed before an electron beam is applied to an area where the capacitance sensor 11 has performed measurement.

As described above, the main control unit 17 instructs the other control unit(s) to perform drawing while correcting the deviation of the drawing position. The control unit to be instructed by the main control unit 17 is one of the control unit 16 and the control unit 13, or a combination of both.

For example, in a multi-beam method for forming an image of a plurality of electron beams on the substrate 3, when positional deviation directions are different among the electron beams, the deviation of the drawing position is to be corrected by using only the control unit 13. On the other hand, when the electron beams uniformly deviate in the same direction in an irradiated area, only control by the control unit 16 can be executed.

In the present exemplary embodiment, the method for correcting the deviation of a drawing position in the electron beam drawing method based on the difference between the surface position measured by the surface position measurement device affected by charging and the surface position measured by the surface position measurement device not affected by charging has been described. According to the present exemplary embodiment, the amount of local charge on the substrate 3 can be obtained by actual measurement, and thus the deviation of a drawing position can be corrected with high accuracy. Moreover, the deviation amount of a drawing position at an actual drawing position can be obtained by measuring the surface position in areas including the pattern area, and thus the deviation of the drawing position can be corrected more accurately than the conventional technique.

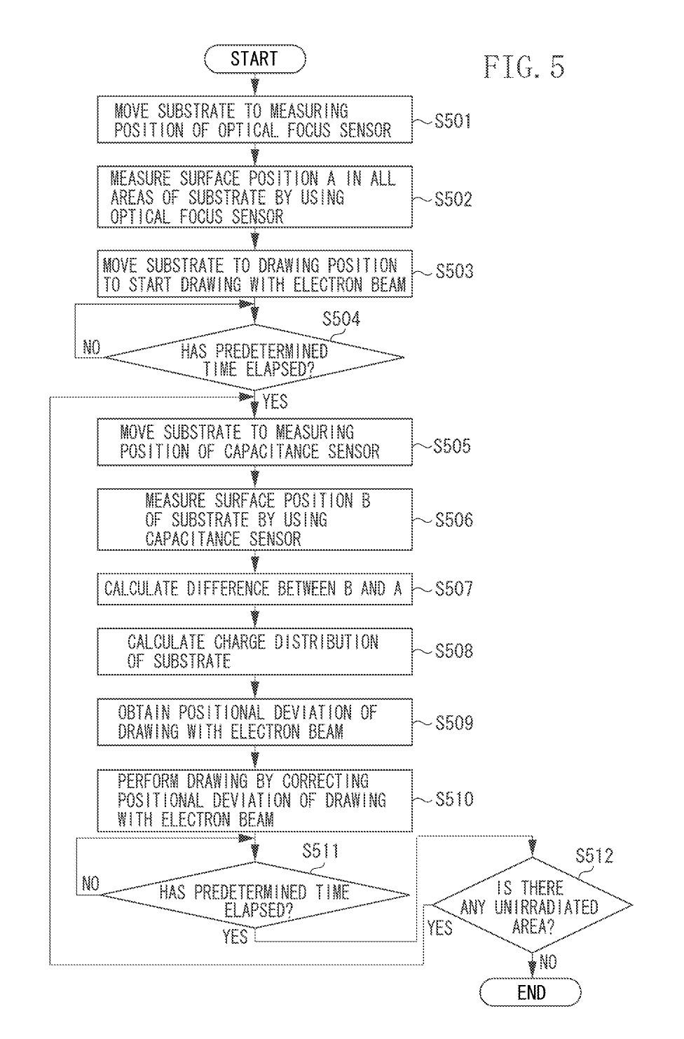

In a second exemplary embodiment, a case will be described where the order for correcting the deviation of a drawing position is different from that of the first exemplary embodiment. A configuration of a drawing apparatus according to the present exemplary embodiment is similar to that of the first exemplary embodiment except for storing in the memory 8 a program for executing processing in a flowchart illustrated in FIG. 5 in addition to the program for executing the processing illustrated in FIG. 3.

FIG. 5 is a flowchart for correcting the deviation of a drawing position implemented by a program according to the second exemplary embodiment. The start time of the flowchart illustrated in FIG. 5A is before drawing a pattern for one layer with an electron beam is started (irradiation is started) and when measuring the position of an alignment mark has been finished by the alignment optical system 8.

First, in step S501, the main control unit 17 instructs the control unit 16 to move the substrate 3 to a measurement position of the optical focus sensor 9. In step S502, the control unit 14 causes the optical focus sensor 9 to measure the surface position A in all areas of the substrate 3.

Then, in step S503, the main control unit 17 instructs the control unit 16 to move the substrate 3 to a drawing position, and instructs the control unit 13 to start drawing. When the main control unit 17 determines that a predetermined time has elapsed after the start of drawing (after the start of irradiation) (YES in step S504), then in step S505, the main control unit 17 instructs the control unit 16 to move the substrate 3 to a measurement position of the capacitance sensor 11. On the other hand, when the main control unit 17 determines that the predetermined time has not elapsed (NO in step S504), the drawing is continued.

In step S506, the control unit 104 causes the capacitance sensor 11 to measure the surface position B. An area for measuring the surface position B is an area where drawing with an electron beam is to be performed before re-measurement by the capacitance sensor 11. In step S507, the main control unit 17 calculates a difference between the surface position B, and the surface position A in the area where the surface position B has been measured. Processing in steps S508 to S511 is similar to that in steps S306 to S309 in the first exemplary embodiment, and thus the description thereof will be omitted.

In step S512, the main control unit 17 determines whether there remains any area that has not yet been irradiated with an electron beam. When the main control unit 17 determines that there remains an unirradiated area (YES in step S512), the processing returns to step S505, and the main control unit 17 instructs the control unit 14 to cause the capacitance sensor 11 to measure the surface position B. Then, similar processing is continued until there is no more unirradiated area.

Thus, according to the present exemplary embodiment, the surface position A is measured in all the areas of the substrate 3 by the optical focus sensor 9 before the start of drawing, and the surface position B is measured by the capacitance sensor 11 after the start of drawing. This enables shortening of time for repeatedly moving the substrate 3 to the measurement position of the optical focus sensor 9. Moreover, no interruption of the pattern drawing operation with the electron beam leads to improvement of throughput.

The above-described second exemplary embodiment is suitable for a case where a drawing pattern is not as complex as that in the first exemplary embodiment and throughput is to be enhanced even if correction accuracy is slightly reduced.

Next, a configuration of a drawing apparatus according to a third exemplary embodiment will be described. In the third exemplary embodiment, the arrangement of the optical focus sensor 9 and the capacitance sensor 11 is different from those of the first and second exemplary embodiments. According to the present exemplary embodiment, the control unit 17 controls the control unit 13, the control unit 14, and the control unit 16, and issues instructions, including measuring a surface position and correcting the deviation of a drawing position, based on the flowchart illustrated in FIG. 3.

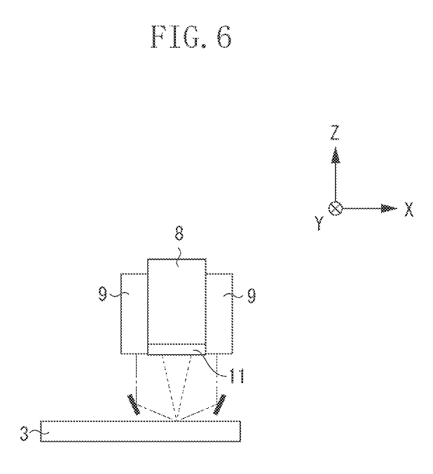

In the first and second exemplary embodiments, the capacitance sensor 11 is located at the lower end portion of the electronic optical system 2. However, in the third exemplary embodiment, as illustrate in FIG. 6, the capacitance sensor 11 is located near the alignment optical system 8 and the optical focus sensor 9. In this case, a measurement area of the optical focus sensor 9 and a measurement area of the capacitance sensor 11 may be identical, or one measurement area includes a part of the other measurement area.

To identify the position of the stage 4 in the Z direction during drawing, an apparatus (not illustrated) that measures a distance between the electronic optical system 2 and the substrate 3 is disposed. This apparatus is not limited to the capacitance sensor 11 as long as it can measure a surface position. Other components of the drawing apparatus are similar to those of the drawing apparatus illustrated in FIG. 1.

By arranging two types of surface position measurement devices as close as possible to each other as in the case of the present exemplary embodiment, the moving distance of the X stage 4a or the Y stage 4b associated with surface position measurement can be shortened. Accordingly, the possibility of deviation of the position coordinates with the movement of the stage 4 can be reduced, and the surface position can be accurately measured. Further, moving time of the stage 4 can be shortened. Thus, throughput reduction in a series of movements until correcting the deviation of a drawing position can be suppressed.

Next, a configuration of a drawing apparatus according to a fourth exemplary embodiment will be described. The fourth exemplary embodiment is realized in combination with the drawing apparatuses of the second and third exemplary embodiments. The capacitance sensor 11 is arranged at two places, i.e., at the lower end portion of the electronic optical system 2 and near the optical focus sensor 9. Other components are similar to those of the drawing apparatus illustrated in FIG. 1.

In the second exemplary embodiment, the capacitance sensor 11 is disposed at the lower end portion of the electronic optical system 2, and the surface position measurement is performed on the entire surface of the substrate 3 by the optical focus sensor 9 before the start of drawing with the electron beam. As a result, the time for moving the stage 4 to the measurement area of the optical focus sensor 9 each time the measurement is performed by the optical focus sensor 9 can be omitted.

In the third exemplary embodiment, the capacitance sensor 11 is disposed near the optical focus sensor 9. By reducing the movement of the stage 4 associated with the surface position measurement, the surface position can be accurately measured, and the moving time of the stage 4 can be omitted.

In the case of the present exemplary embodiment where the capacitance sensor 11 is arranged at two places, a user can select the capacitance sensor 11 to be used according to complexity of a drawing pattern, accuracy, and throughput.

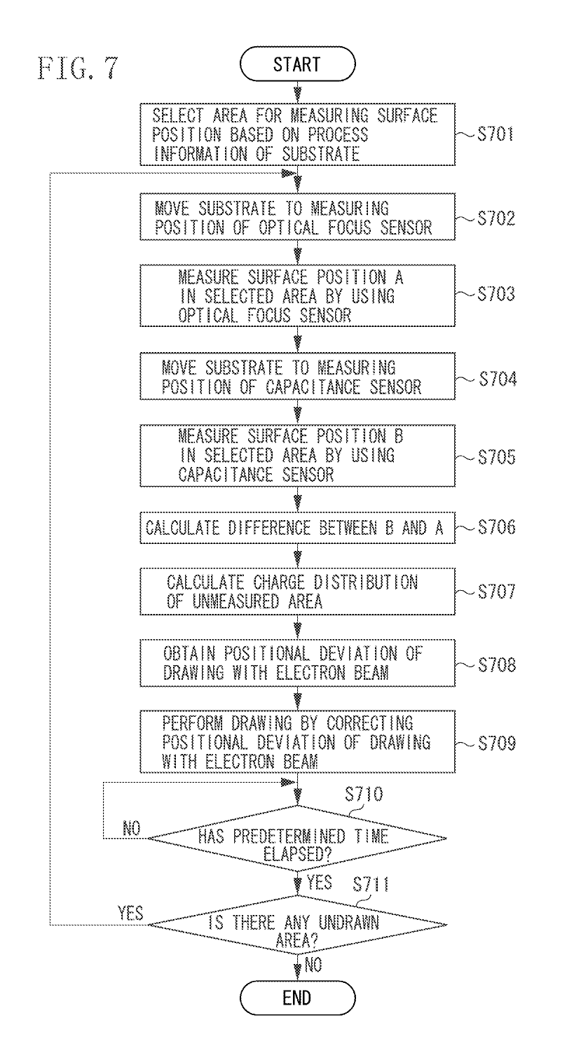

Next, a drawing apparatus according to a fifth embodiment will be described. A configuration of the drawing apparatus according to the fifth exemplary embodiment is any one of the configurations of the drawing apparatuses according to the first to fourth exemplary embodiments, and a program illustrated in a flowchart of FIG. 7 is stored in a memory 18. According to the fifth embodiment, areas to be measured by the optical focus sensor 9 serving as the first measurement unit and the capacitance sensor 11 serving as the second measurement unit can be selected.

A flow of processing to be executed by the main control unit 17 according to the fifth exemplary embodiment will be described with reference to the flowchart illustrated in FIG. 7, based on the configuration of the drawing apparatus illustrated in FIG. 1.

First, before drawing, in step S701, the main control unit 17 selects an area where a surface position is to be measured for correcting the deviation of a drawing position caused by charging. For example, an area having a small reflectance difference can be selected as a measurement area in consideration of the material or shape of each semiconductor layer formed on the substrate 3. This can reduce measurement errors of the optical focus sensor 9 caused by reflectance, and thus correction accuracy of a drawing position can be improved. Such determination for selecting a measurement area may be performed according to an instruction from the user or based on conditions previously set in the drawing apparatus.

If, based on the data stored in the past, an area where a charge distribution formed according to a pattern of a semiconductor layer on the substrate 3 is considered to be uniform and an area where the charge distribution is considered to be complex have been previously known, the density of these areas and the density of areas where surface position measurement is to be performed can be associated with each other. As a result, time for measuring surface positions in areas where measurement is unnecessary can be shortened.

A procedure of processing in steps S702 to S706 is similar to that of processing in steps S301 to S305 in the flowchart illustrated in FIG. 3, and thus the detailed description thereof will be omitted. Areas where measurement is carried out by the optical focus sensor 9 and the capacitance sensor 11 are different from those of the other exemplary embodiments in that the areas are limited to those selected in the processing in step S701.

In step S707, the main control unit 17 interpolates an area where measurement has not been performed to obtain the charge distribution on the surface of the substrate 3. In this case, the amount of charge in the local area obtained in step S706 is used. Processing in steps S708 to S711 is similar to that in steps S307 to S310 of the flowchart illustrated in FIG. 3, and thus the description thereof will be omitted.

Here, only the method for selecting measurement areas at the time of starting the surface position measurement has been described. However, the application range of the present exemplary embodiment is not limited thereto. For example, after the surface position of the substrate 3 is measured by the optical focus sensor 9 in step S703, an area where the surface position B is to be measured can be determined based on information about the surface position A.

The present exemplary embodiment is characterized in that an area on the substrate 3 where a surface position is to be measured is selected beforehand and therefore is suitable when a charge distribution is generated in a wide range of the substrate 3 or when a plurality of similar charge distributions is formed on the substrate 3. A surface position is measured only in the selected area, and thus this method may have an advantage over the method for performing measurement in all the areas of the substrate 3 in that measurement time can be shortened without reducing the accuracy of correcting the deviation of a drawing position.

Hereinafter, other exemplary embodiments will be described below. The process of calculating the charge distribution may be omitted by directly calculating the positional deviation of drawing with an electron beam from a measurement result of a surface position. A method for obtaining the charge distribution or the surface position deviation is not limited to calculation. These can be obtained by referring to a table indicating a relationship between the difference in surface position and the deviation amount of a drawing position.

The first to fifth exemplary embodiments have been described using an example where the timing of measuring the surface position is after the elapse of a predetermined time. However, the measurement timing is not limited thereto. Charging of the substrate 3 occurs due to drawing. Thus, when an integrated irradiation amount is large or when a pattern density is high, a surface position is to be measured each time the respective values reach a predetermined value.

Alternatively, it is possible to make a setting to perform surface position measurement at the completion timing of drawing on a chip-by-chip basis, the completion timing of drawing for each column, or the completion timing of drawing for each stripe. To improve the correction accuracy of positional deviation due to charging, a surface position is to be measured as frequently as possible because each time a certain point is irradiated with an electron beam, the charge distribution in the surrounding area of the point changes.

Not only in the first exemplary embodiment but also in the other exemplary embodiments, the timing of obtaining the measurement error of capacitance or the deviation amount of an electron beam irradiation position based on measured values of surface positions can be any time before an area where a surface position has been measured is irradiated with an electron beam.

Generally, in the case of manufacturing a semiconductor device, the same pattern is often drawn on a lot-by-lot basis. In other words, in many cases, the process of drawing the same pattern on the surfaces of the substrates where semiconductor layers having the same structure are formed is continuously performed.

In the case of drawing the same pattern on the substrates having the same structure, similar charge distributions may be generated. Accordingly, data for correcting the deviation of a drawing position obtained for the first substrate in a lot can be used for the second or later substrates in the same lot, which are different from the first substrate in the lot. This processing can reduce a repeated measurement operation, thereby improving throughput.

Using the existing data is not limited to the case of substrates having the same structure or the case of drawing the same pattern. The existing data can be used in the case of substrates having a similar structure or the case of drawing a similar pattern as long as no distortion occurs in the pattern to be formed.

When the data on the charge distribution in pattern drawing performed in the past remains in the memory 18, measured values of surface positions and data for correcting the deviation of a drawing position for one substrate can be applied to a plurality of other substrates. Surface positions for one substrate is measured to obtain correction data, and surface position measurement is omitted in the case of drawing on other substrates, thereby enabling the deviation of a drawing position to be accurately corrected without any reduction of throughput.

The above-described surface position measurement by the optical focus sensor 9 may be carried out outside the vacuum chamber 12 of the drawing apparatus. When the surface position on the substrate 3 is measured beforehand outside the vacuum chamber 12, the surface measurement can be performed by another optical sensor, an air gauge, or an ultrasonic distance measurement device.

If charge has been removed from the substrate 3, a capacitance sensor can be used in place of the optical focus sensor 9. The capacitance sensor to be used in this case may be the same measurement device as that for measuring the surface position after the start of drawing.

The first to fifth exemplary embodiments have been described, mainly using an example where the capacitance sensor and the optical sensor are used. However, the present invention is not limited thereto. An exemplary embodiment where the same physical amount is detected by two types of sensors having different characteristics in terms of charging so that the deviation of a drawing position is accurately corrected based on a result of the detection is included in exemplary embodiments of the present invention.

A method for manufacturing articles (e.g., semiconductor integrated circuit element, liquid crystal display element, compact disk-rewritable (CD-RW), or reticle) according to an exemplary embodiment of the present invention includes a process of irradiating a substrate such as a wafer or glass with a beam by using the drawing apparatus described in each of the aforementioned exemplary embodiments, and a process of developing the substrate where a pattern has been drawn. Further, the method may include other known processes (e.g., oxidation, film forming, deposition, doping, planarization, etching, resist peeling, dicing, bonding, and packaging).

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefits of Japanese Patent Application No. 2013-091563 filed Apr. 24, 2013 and Japanese Patent Application No. 2014-025733 filed Feb. 13, 2014, which are hereby incorporated by reference herein in their entirety.

What is claimed is:

1. An apparatus for irradiating a charged particle beam comprising:
an optical system configured to irradiate a substrate with the charged particle beam;
a control unit configured to control an irradiation position of the charged particle beam; and
a first measurement unit and a second measurement unit each configured to measure a surface position of the substrate,
wherein the first measurement unit and the second measurement unit have different characteristics in terms of charging, and
wherein the control unit controls the irradiation position of the charged particle beam on the substrate based on values measured by the first measurement unit and the second measurement unit.

2. The apparatus according to claim 1, wherein the apparatus is configured to form a pattern, and
wherein the first measurement unit and the second measurement unit each measure the surface position within an area where the pattern is to be formed.

3. The apparatus according to claim 1, wherein the control unit changes the irradiation position of the charged particle beam in a direction for correcting a deviation of the irradiation position of the charged particle beam, based on a difference between the values measured by the first measurement unit and the second measurement unit.

4. The apparatus according to claim 1, wherein the control unit obtains a charge distribution on a surface of the substrate using the values measured by the first measurement unit and the second measurement unit, and controls the irradiation position of the charged particle beam based on the charge distribution.

5. The apparatus according to claim 1, wherein the control unit controls, based on the values measured on the substrate by the first measurement unit and the second measurement unit, an irradiation position of the charged particle beam to be applied to a substrate different from the substrate.

6. The apparatus according to claim 1, wherein the second measurement unit measures the surface position while irradiating the charged particle beam.

7. The apparatus according to claim 1, wherein the second measurement unit is disposed in at least one of a lower end portion of the optical system and a position closer to the first measurement unit than the lower end portion of the optical system.

8. The apparatus according to claim 7, wherein the second measurement unit is disposed in both the lower end portion of the optical system and the position closer to the first measurement unit than the lower end portion of the optical system, and the second measurement unit to be used for measurement can be selected.

9. The apparatus according to claim 1, wherein the control unit controls, based on the values measured by the first measurement unit and the second measurement unit, at least one of a stage that moves holding the substrate and the optical system.

10. The apparatus according to claim 1, wherein the second measurement unit is a capacitance sensor.

11. The apparatus according to claim 1, wherein the first measurement unit is an optical sensor.

12. The apparatus according to claim 10, wherein surface positions of a plurality of points on the same substrate are measured by the capacitance sensor disposed at a plurality of places.

13. The apparatus according to claim 11, wherein a light source of the optical sensor emits light including a plurality of peak wavelengths.

14. An apparatus for irradiating a charged particle beam comprising:
an irradiation unit configured to irradiate a substrate with the charged particle beam;
a control unit configured to control an irradiation position of the charged particle beam; and
an optical sensor and a capacitance sensor each configured to measure a surface position of the substrate,
wherein the control unit controls the irradiation position of the charged particle beam on the substrate, based on values measured by the optical sensor and the capacitance sensor.

15. An apparatus for irradiating a charged particle beam comprising:
an irradiation unit configured to irradiate a substrate with the charged particle beam;
a control unit configured to control an irradiation position of the charged particle beam; and
a capacitance sensor and a sensor different in type from the capacitance sensor,
wherein the control unit controls the irradiation position of the charged particle beam on the substrate based on detection results by the respective sensors so that a positional deviation caused by charging is reduced.

16. The apparatus according to claim 15, wherein the control unit changes the irradiation position of the charged particle beam based on a difference between the detection results by the respective sensors.

17. The apparatus according to claim 1, wherein the charged particle beam is an electron beam.

18. A method for irradiation of a charged particle beam, the method comprising:
irradiating a substrate with the charged particle beam;
measuring a surface position of the substrate by using a first measurement unit;
measuring a surface position of the substrate by using a second measurement unit having a different characteristic in terms of charging from the first measurement unit; and
controlling an irradiation position of the charged particle beam on the substrate based on values measured by the first measurement unit and the second measurement unit.

19. A method for irradiation of a charged particle beam, the method comprising:
irradiating a substrate with the charged particle beam;
measuring a surface position of the substrate before starting the irradiation with the charged particle beam;
measuring a surface position of the substrate by using a measurement unit configured to output a measured value according to an amount of charge on a surface of the substrate after starting the irradiation with the charged particle beam; and
controlling an irradiation position of the charged particle beam on the substrate based on the respective measured surface positions.

20. A method for manufacturing an article, the method comprising:
irradiating a substrate with a charged particle beam by using an apparatus for irradiating a charged particle beam; and
developing the irradiated substrate,
wherein the apparatus comprises:
an optical system configured to irradiate the substrate with the charged particle beam;
a control unit configured to control an irradiation position of the charged particle beam; and
a first measurement unit and a second measurement unit each configured to measure a surface position of the substrate,
wherein the first measurement unit and the second measurement unit have different characteristics in terms of charging, and
wherein the control unit controls the irradiation position of the charged particle beam on the substrate based on values measured by the first measurement unit and the second measurement unit.
